(19) United States
(12) Patent Application Publication
(10) Pub. No.: US 2008/0012127 A1
(43) Pub. Date: Jan. 17, 2008

(54) Insulation structure for multilayer passive elements and fabrication method thereof

(75) Inventors: Ming-Tsan Tseng, Tainan City (TW); Yung-Chi Chen, Taichung City (TW)

Correspondence Address: BIRCH STEWART KOLASCH & BIRCH, PO BOX 747, FALLS CHURCH, VA, 22040-0747, US

(73) Assignee: INPAQ TECHNOLOGY CO., LTD.

(21) Appl. No.: 11/475,945

(22) Filed: Jun. 28, 2006

(51) Int. Cl. H01L 23/48

(52) U.S. Cl. 257/734

(57) ABSTRACT

The present invention discloses an insulation structure for multilayer passive elements and a fabrication method thereof, wherein a protective insulation film is formed on the surface of a multilayer passive element; a transformation process is performed at a transformation temperature to convert the protective insulation films within the areas exactly below external electrodes into conductors, and the other portion of the protective insulation film still remains insulating. The present invention can protect passive elements from corrosion in the succeeding procedures with a simple fabrication process and without extra material and equipments. Further, the fabrication speed of the present invention is the same as that of a common external-electrode coating, and the fabrication of the present invention can also be automated for mass-production.

### FIELD OF THE INVENTION

The present invention relates to an insulation structure and a fabrication method thereof, particularly to an insulation structure for SMT multilayer passive elements and a fabrication method thereof, wherein a protective insulation film is formed on the surface of a passive element to protect the passive element from corrosion in the succeeding fabrication processes.

### BACKGROUND OF THE INVENTION

To increase functions, reduce size, and decrease power consumption, electronic products, especially 3C products (computer, communication and consumer products), are tending to be slim and lightweight, and the sizes of the multilayer passive elements used therein are also reduced as much as possible to meet the tendency. To secure the attachment of the multilayer passive element on the circuit board, the external electrodes of the multilayer passive element and the tin soldering paste on the circuit substrate via IR reflow or wave soldering are fused to form a full circuit and obtain the desired performance.

Refer to from FIG. 1 to FIG. 3 schematically showing a simple-type multilayer passive element, an array-type multilayer passive element and a special-type multilayer passive element respectively. As shown in FIG. 1, the simple-type multilayer passive element has a body 11 and two external electrodes 12 respectively disposed on two ends of the body 11. As shown in FIG. 2, the array-type multilayer passive element has a body 21 and multiple external electrodes 22 arranged in array and respectively disposed on twp opposite surfaces of the body 21. As shown in FIG. 3, the special-type multilayer passive element has a body 31 and multiple external electrodes 32, which may be disposed on the required surfaces of the body 31.

Usually, the external electrode is made of a silver-metal-containing paste, and the surface of the external electrode is plated with a soldering interface layer via a surface-treatment technology to assist the fusion of the external electrode and a soldering pad and implement SMT (Surface Mount Technology) process.

The solutions of the surface treatment are usually of high acidity or high alkalinity. Therefore, the surface of a multilayer passive element is apt to be corroded by a surface-treatment solution, and the electrical performance of the multilayer passive element is likely to be degraded.

In the conventional technologies, the formation methods of external electrodes, which can also prevent the body of a passive element from corrosion during fabrication, are briefly described as follows:
(1) Method 1: Using a precious-metal-containing paste dipped=on the surface of the body of a multilayer passive element to form the so-called electroplating-free electrode so that the external electrode of the multilayer passive element can be directly fused with the tin soldering paste on soldering pads. Such a method adopts the dipped process used in fabricating common external electrodes and can be automated to promote fabrication efficiency._However, the viscosity of the tin soldering paste decreases due to the temperature rise in the area where the external electrodes contact the tin soldering paste and the tin soldering paste begins to fuse from the external edge of the tin soldering paste where temperature is highest. The material of the electroplating-free electrodes is inhomogeneous to the tin soldering paste; therefore, after IR reflow or wave soldering, the raising of solder is inferior to that of surface-treated elements. Further, with the tendency that the size of multilayer passive elements is gradually decreasing, the reliability test of the elements fabricated in such a method is likely to fail. Besides, the price of precious-metal is expensive and likely to fluctuate, and thus, the material cost of such a method is greater than that of other methods.
(2) Method 2: A protective insulation film of a non-crystalline material, such as a glass or a polymer material is formed on the surface of the body of a multilayer passive element, and then, a stripping/cleaning process is performed to expose internal electrodes so that external electrodes can be coated directly on the internal electrodes. Then, the body of the passive element can be protected in the succeeding surface-treatment process of forming a soldering interface layer. As such a method needs an additional stripping/cleaning process, materials and equipments have to be reconsidered, which causes much difficulty in adopting such a method.
(3) Method 3: A protective insulation film is formed on the surface of the body of a multilayer passive element via a film-growth method. The effect of the protective insulation film is the same as that of Method 2, but such a method is free from the abovementioned stripping/cleaning process. Therefore, such a method can reduce the fabrication cost and time of multilayer passive elements. However, the resistance of the protective insulation film will be reduced after IR reflow or wave soldering, i.e. the leakage current of the passive element will increase when the passive element has been installed on a circuit. Thus, the reliability of the passive elements fabricated in such a method is degraded. Further, as the process of forming a high-resistance surface is hard to control in this method, it also has a high defect rate in insulation. Therefore, how to form a stable protective insulation film on the surface of the body without any chemical reaction on the surface of the body becomes an important problem of this method.
(4) Method 4: A metal diffusion process is adopted to form a protective insulation film of high resistance. As this method has to control the diffusion of metallic ions, and the parameters of forming high resistance on the surface are hard to control, it is the most difficult of all the methods. Further, as such a method has to utilize the equipments used in the field of semiconductor, the fabrication cost thereof is pretty high.

From those discussed above, it is known that the conventional technologies still have many disadvantages and need to be improved further.

### SUMMARY OF THE INVENTION

The primary objective of the present invention is to provide an insulation structure for multilayer passive elements and a fabrication method thereof, wherein a protective insulation film is formed on the surface of a multilayer passive element to protect the body of the passive element from corrosion in the succeeding surface-treatment process.

Another objective of the present invention is to provide an insulation structure for multilayer passive elements and a fabrication method thereof, which can utilize the original dipping equipment to fabricate SMT multilayer passive elements and can be automated to realize the mass-production thereof and promote the yield thereof.

Further objective of the present invention is to provide an insulation structure for multilayer passive elements and a fabrication method thereof, wherein a protective insulation film is used to protect the body of multilayer passive elements in the succeeding surface-treatment process in order to avoid the corrosion phenomenon in the succeeding fabrication procedures and avoid the leakage-current increase and the high defect yield rate in insulation, which result from a coating process.

To achieve the abovementioned objectives, an enveloping process is performed to wrap a passive element with a protective insulation film; the enveloping process may be a dipping process, a film-coating process (such as a vapor deposition process or a sputtering process), or a printing process. After the enveloping process, the passive element wrapped by the protective insulation film is dried at a specified temperature. Next, external electrodes are coated on the protective insulation film. Next, the passive element coated with external electrodes is processed at a transformation temperature, and the protective insulation films within the areas exactly below the external electrodes are converted into conductors. Thus, internal electrodes in the body of the passive element are connected with the external electrodes, and no extra stripping process is needed, and the other portion of the protective insulation film still remains insulating. The present invention utilizes a temperature change to transform the protective insulation films within the areas exactly below the external electrodes into conductors from insulators, and the present invention not only can apply to the single-type multilayer passive element, but also can apply to the array-type and the special-type multilayer passive elements. Via the present invention, the passive elements not only can be free from the corrosion problem in the succeeding processes but also can be automatically mass-produced without any extra equipment.

### BRIEF DESCRIPTION OF THE DRAWINGS

FIG. 1 is a diagram schematically showing a simple-type multilayer passive element.

FIG. 2 is a diagram schematically showing an array-type multilayer passive element.

FIG. 3 is a diagram schematically showing a special-type multilayer passive element.

FIG. 4 is a diagram schematically showing the structure of a single-type multilayer passive element according to a first embodiment of the present invention.

FIG. 5 is a diagram schematically showing the structure of an array-type multilayer passive element according to a first embodiment of the present invention.

FIG. 6 is a diagram schematically showing the structure of a special-type multilayer passive element according to a first embodiment of the present invention.

FIG. 7 is a diagram schematically showing the structures of a single-type multilayer passive element according to a second embodiment of the present invention.

FIG. 8 is a diagram schematically showing the structures of an array-type multilayer passive element according to a second embodiment of the present invention.

FIG. 9 is a diagram schematically showing the structures of a special-type multilayer passive element according to a second embodiment of the present invention.

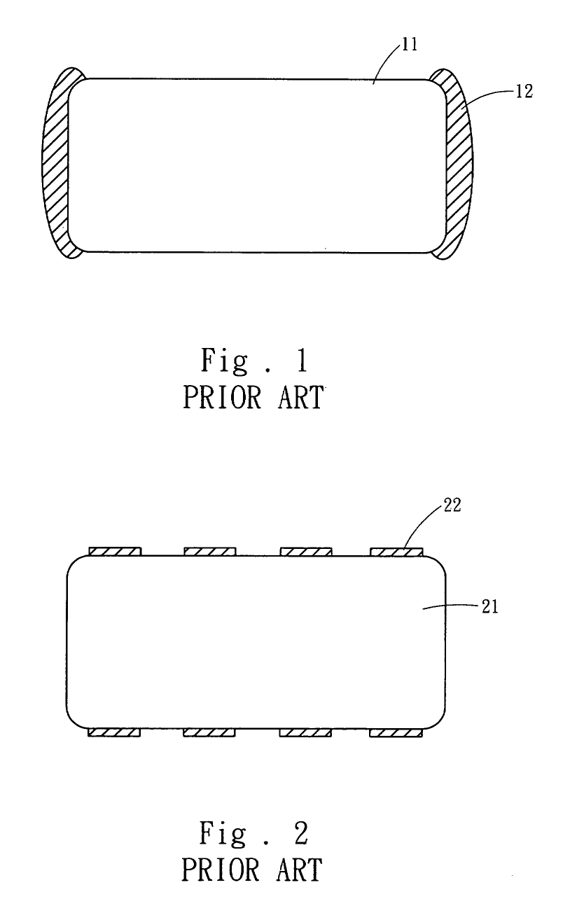

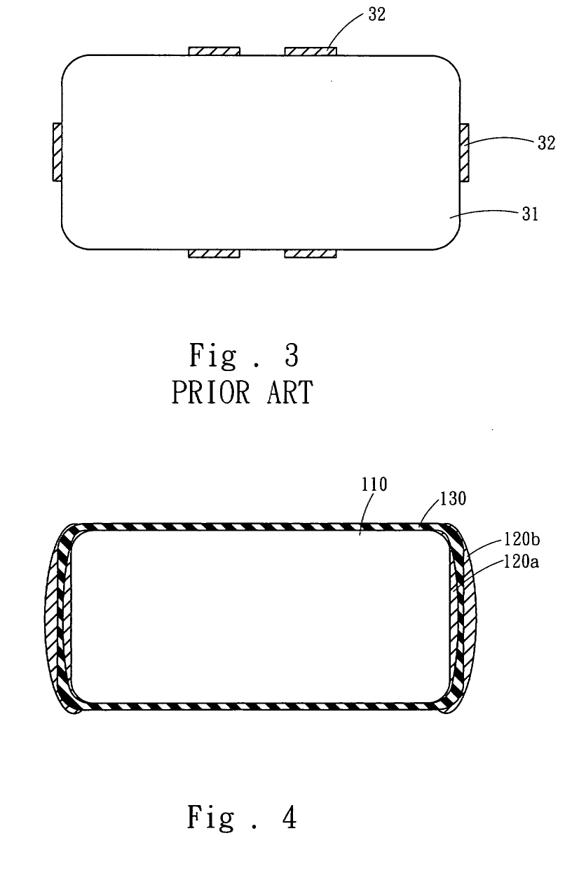

### DETAILED DESCRIPTION OF THE PREFERRED EMBODIMENTS

The technical contents and embodiments of the present invention are to be described below in detail in cooperation with the drawings.

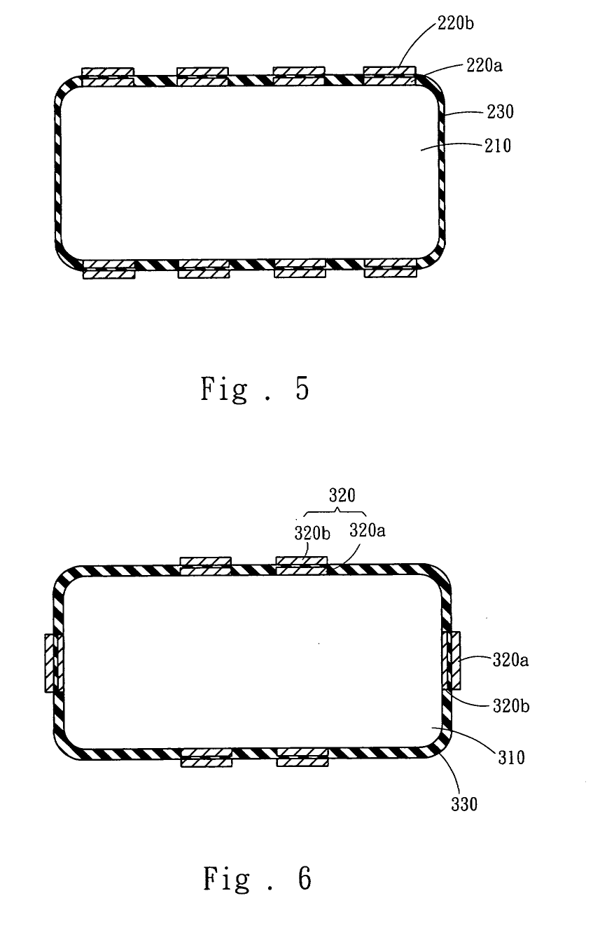

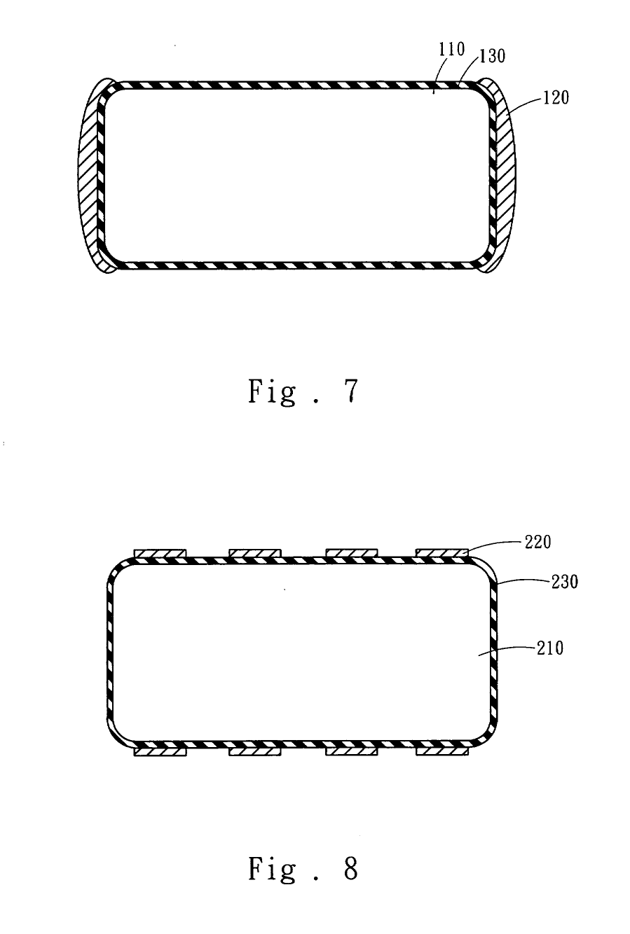

Refer to from FIG. 4 to FIG. 6 schematically showing the structures of a single-type multilayer passive element, an array-type multilayer passive element and a special-type multilayer passive element according to a first embodiment of the present invention respectively. The insulation structures of the present invention and the fabrication method thereof according to the first embodiment of the present invention are described as follows:
(a) Forming a body 110, 210, or 310 of a passive element;
(b) Dipping multiple first external electrodes 120a, 220a, or 320a on the surface of the body 110, 210, or 310 with the first external electrodes 120a, 220a, or 320a electrically connected to the body 110, 210, or 310. The material of the first external electrodes 120a, 220a, or 320a selected from the group consisting of silver, copper, palladium, platinum, and gold or from the alloys of the aforementioned metallic materials;
(c) Performing an enveloping process to form a protective insulation film 130, 230, or 330 on the surface of the body 110, 210, or 310 with the protective insulation film 130, 230, or 330 selected from the group consisting of alkaline-group insulation materials, alkaline-earth-group insulation materials, silicon-based insulation materials, lead-based insulation materials, boron-based insulation materials, titanium-based insulation materials, zinc-based insulation materials, and aluminum-based insulation materials, wherein the enveloping process may be a dipping process, a film-coating process (such as a vapor deposition process or a sputtering process), or a printing process, and the passive element wrapped by the protective insulation film is dried at a temperature ranging from 70° C. to 300° C. for from 10 minutes to 2 hours to form a dried protective insulation film 130, 230, or 330 with a thickness ranging from 20 nm to 5 mm;
(d) Dipping multiple second external electrodes 120b, 220b, or 320b on the surface of the protective insulation film 130, 230, or 330 and within the areas exactly above the first external electrodes 120a, 220a, or 320a with the material of second external electrodes 120b, 220b, or 320b selected from the group consisting of silver, copper, palladium, platinum, and gold or from the alloys of the aforementioned metallic materials; and
(e) Processing the passive element at a transformation temperature ranging from 150° C. to 1000° C. for from 30 minutes to 2 hours to convert the protective insulation films 130, 230, or 330 within the areas exactly below the second external electrodes 120b, 220b, or 320b into conductors so that the first external electrodes 120a, 220a, or 320a will be connected with the second external electrodes 120b, 220b, or 320b, and the other portion of the protective insulation film 130, 230, or 330 may still remain insulating.

Via the abovementioned protective insulation film 130, 230, or 330, the body 110, 210, or 310 can be free from corrosion in the succeeding processes. The surface of the second external electrodes 120b, 220b, or 320b will be plated with a soldering interface layer to assist the fusion between the external electrodes and soldering pads and implement the SMT attachment of the multilayer passive element.

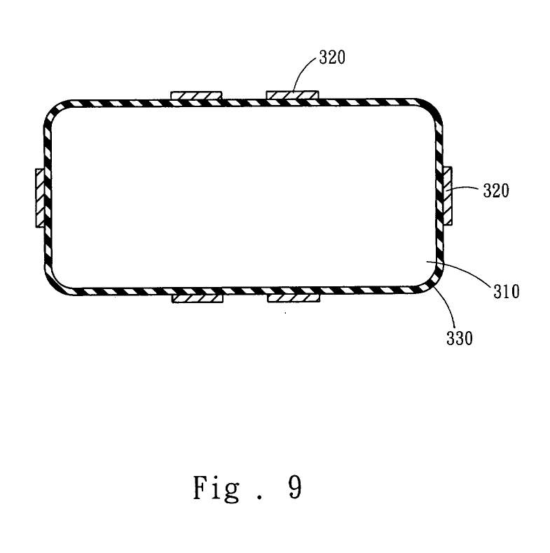

Refer to from FIG. 7 to FIG. 9 schematically showing the structures of a single-type multilayer passive element, an array-type multilayer passive element and a special-type multilayer passive element according to a second embodiment of the present invention respectively. The insulation structures of the present invention and the fabrication method thereof according to the second embodiment of the present invention are described as follows:
(a) Forming a body 110, 210, or 310 of a passive element;
(b) Performing an enveloping process to form a protective insulation film 130, 230, or 330 on the surface of the body 110, 210, or 310 with the protective insulation film 130, 230, or 330 selected from the group consisting of alkaline-group insulation materials, alkaline-earth-group insulation materials, silicon-based insulation materials, lead-based insulation materials, boron-based insulation materials, titanium-based insulation materials, zinc-based insulation materials, and aluminum-based insulation materials, wherein the enveloping process may be a dipping process, a film-coating process (such as a vapor deposition process or a sputtering process), or a printing process, and the passive element wrapped by the protective insulation film 130, 230, or 330 is dried at a temperature ranging from 70° C. to 300° C. for from 10 minutes to 2 hours to form a dried protective insulation film 130, 230, or 330 with a thickness ranging from 20 nm to 5 mm;
(c) Dipping multiple external electrodes 120, 220, or 320 on the surface of the protective insulation film 130, 230, or 330 with the material of the external electrodes 120, 220, or 320 selected from the group consisting of silver, copper, palladium, platinum, and gold or from the alloys of the aforementioned metallic materials; and
(d) Processing the passive element at a transformation temperature ranging from 150° C. to 1000° C. for from 30 minutes to 2 hours to convert the protective insulation films 130, 230, or 330 within the areas exactly below the external electrodes 120, 220, or 320 into conductors so that the external electrodes 120, 220, or 320 will be connected with the body 110, 210, or 310, and the other portion of the protective insulation film 130, 230, or 330 may still remain insulating.

Via the abovementioned protective insulation film 130, 230, or 330, the body 110, 210, or 310 can be free from corrosion in the succeeding processes. The surface of the external electrodes 120, 220, or 320 will be plated with a soldering interface layer to assist the fusion between the external electrodes and soldering pads and implement the SMT attachment of the multilayer passive element.

The present invention is characterized in the structure of the protective insulation film of multilayer passive elements and the fabrication method thereof, which are to implement the SMT attachment of the multilayer passive elements. In comparison with the conventional technologies, the present invention has the following advantages:
1. In the present invention, the protective insulation films 130, 230, or 330 within the areas exactly below the external electrodes are converted into conductors after the processing at a transformation temperature, and the other portion of the protective insulation film 130, 230, or 330 still remains insulating; therefore, no extra stripping process of the protective insulation films 130, 230, or 330 is needed to remove the protective insulation films 130, 230, or 330 within the areas exactly below the external electrodes; thereby, not only local damage of the protective insulation film can be avoided, but also the fabrication time, cost and equipments can be saved.
2. In the present invention, the structure of the protective insulation film 130, 230, or 330 of multilayer passive elements not only can be fabricated with the original equipments, but also can be mass-produced automatically to promote the yield thereof.
3. In the present invention, the structure of the protective insulation film 130, 230, or 330 of multilayer passive elements and the fabrication method thereof of can extensively apply to various types of multilayer passive elements, including: the single-type, the array-type and the special-type multilayer passive elements; the fabrication equipment and the fabrication process thereof are identical for various types of passive elements, and no extra equipment and process are needed, which benefits cost reduction very much.
4. In the present invention, the structure of the protective insulation film 130, 230, or 330 of multilayer passive elements and the fabrication method thereof can extensively apply to various sizes of multilayer passive elements, including: 1.0 mm long×0.5 mm wide passive elements, 0.5 mm long×0.25 mm wide passive elements, and further smaller passive elements.

The present invention has been clarified with the preferred embodiments described above; however, it is not intended to limit the scope of the present invention, and any equivalent modification and variation according to the spirit of the present invention is to be also included with the scope the claims of the present invention.

What is claimed is:

1. An insulation structure for multilayer passive elements, applying to SMT (Surface Mount Technology) passive elements, and comprising:
a body of a passive element;
multiple first external electrodes, installed on the surface of said body;
a protective insulation film, enveloping the surface of said body; and
multiple second external electrodes, installed on the protective insulation films within the areas exactly above said first external electrodes;
wherein said protective insulation films within the areas exactly below said second external electrodes are converted into conductors via a transformation process at a transformation temperature so that said first external electrodes can be connected with said second external electrodes, and the other portion of said protective insulation film still remains insulating.

2. The insulation structure for multilayer passive elements according to claim 1, wherein the materials of said first external electrodes and said second external electrodes are selected from the group consisting of silver, copper, palladium, platinum, and gold or from the alloys thereof.

3. The insulation structure for multilayer passive elements according to claim 1, wherein the thickness of said protective insulation film ranges from 20 nm to 5 mm.

4. The insulation structure for multilayer passive elements according to claim 1, wherein the material of said protective insulation film is selected from the group consisting of alkaline-group insulation materials, alkaline-earth-group insulation materials, silicon-based insulation materials, lead-based insulation materials, boron-based insulation materials, titanium-based insulation materials, zinc-based insulation materials, and aluminum-based insulation materials.

5. The insulation structure for multilayer passive elements according to claim 1, wherein said transformation temperature ranges from 150° C., to 1000° C.

6. An insulation structure for multilayer passive elements, applying to SMT (Surface Mount Technology) passive elements, and characterized by:
a body of a passive element;
a protective insulation film, enveloping the surface of said body; and
multiple external electrodes, installed on said protective insulation film;
wherein the protective insulation films within the areas exactly below said external electrodes are converted into conductors via a transformation process at a transformation temperature so that said external electrodes can be connected with said body, and the other portion of said protective insulation film still remains insulating.

7. The insulation structure for multilayer passive elements according to claim 6, wherein the material of said external electrodes is selected from the group consisting of silver, copper, palladium, platinum, and gold or from the alloys thereof.

8. The insulation structure for multilayer passive elements according to claim 6, wherein the thickness of said protective insulation film ranges from 20 nm to 5 mm.

9. The insulation structure for multilayer passive elements according to claim 6, wherein the material of said protective insulation film is selected from the group consisting of alkaline-group insulation materials, alkaline-earth-group insulation materials, silicon-based insulation materials, lead-based insulation materials, boron-based insulation materials, titanium-based insulation materials, zinc-based insulation materials, and aluminum-based insulation materials.

10. The insulation structure for multilayer passive elements according to claim 6, wherein said transformation temperature ranges from 150° C. to 1000° C.

11. A fabrication method of an insulation structure for multilayer passive elements, comprising the following steps:
(a) Forming a body of a passive element;
(b) Forming multiple first external electrodes on the surface of said body;
(c) Performing an enveloping process and then a drying process at a drying temperature to form a protective insulation film enveloping said body;
(d) Forming multiple second external electrodes on the surface of said protective insulation film and within the areas exactly above said first external electrodes with said protective insulation film interposed between said second external electrodes and said first external electrodes; and
(e) Performing a transformation process at a transformation temperature to convert the protective insulation films within the areas exactly below said second external electrodes into conductors so that said first external electrodes can be electrically connected with said second external electrodes, and the other portion of said protective insulation film still remains insulating.

12. The fabrication method of an insulation structure for multilayer passive elements according to claim 11, wherein the materials of said first external electrodes and said second external electrodes are selected from the group consisting of silver, copper, palladium, platinum, and gold or from the alloys thereof.

13. The fabrication method of an insulation structure for multilayer passive elements according to claim 11, wherein said enveloping process may be a dipping process, a film-coating process, or a printing process.

14. The fabrication method of an insulation structure for multilayer passive elements according to claim 11, wherein the material of said protective insulation film is selected from the group consisting of alkaline-group insulation materials, alkaline-earth-group insulation materials, silicon-based insulation materials, lead-based insulation materials, boron-based insulation materials, titanium-based insulation materials, zinc-based insulation materials, and aluminum-based insulation materials.

15. The fabrication method of an insulation structure for multilayer passive elements according to claim 11, wherein said drying process is performed at a drying temperature ranging from 70° C. to 300° C. for from 10 minutes to 2 hours.

16. The fabrication method of an insulation structure for multilayer passive elements according to claim 11, wherein said transformation process is performed at a transformation ranging from 150° C. to 1000° C. for from 30 minutes to 2 hours.

17. A fabrication method of an insulation structure for multilayer passive elements, comprising the following steps:
(a) Forming a body of a passive element;
(b) Performing an enveloping process and then a drying process at a drying temperature to form a protective insulation film enveloping said body;
(c) Forming multiple external electrodes on the surface of said protective insulation film; and
(d) Performing a transformation process at a transformation temperature to convert the protective insulation films within the areas exactly below said external electrodes into conductors so that said external electrodes can be connected with said body, and the other portion of said protective insulation film still remains insulating.

18. The fabrication method of an insulation structure for multilayer passive elements according to claim 17, wherein the material of said external electrodes is selected from the group consisting of silver, copper, palladium, platinum, and gold or from the alloys thereof.

19. The fabrication method of an insulation structure for multilayer passive elements according to claim 17, wherein said enveloping process may be a dipping process, a film-coating process, or a printing process.

20. The fabrication method of an insulation structure for multilayer passive elements according to claim 17, wherein the material of said protective insulation film is selected from the group consisting of alkaline-group insulation materials, alkaline-earth-group insulation materials, silicon-based insulation materials, lead-based insulation materials, boron-based insulation materials, titanium-based insulation materials, zinc-based insulation materials, and aluminum-based insulation materials.

21. The fabrication method of an insulation structure for multilayer passive elements according to claim 17, wherein said drying process is performed at a drying temperature ranging from 70° C. to 300° C. for from 10 minutes to 2 hours.

22. The fabrication method of an insulation structure for multilayer passive elements according to claim 17, wherein said transformation process is performed at a transformation ranging from 150° C. to 1000° C. for from 30 minutes to 2 hours.
